(19) United States
(12) Patent Application Publication
(10) Pub. No.: US 2023/0411471 A1
(43) Pub. Date: Dec. 21, 2023

(54) SEMICONDUCTOR DEVICES

(71) Applicant: Samsung Electronics Co., Ltd., Suwon-si (KR)

(72) Inventors: Seungmin Cha, Suwon-si (KR); Minchan Gwak, Suwon-si (KR); Donghoon Hwang, Suwon-si (KR); Sora You, Suwon-si (KR); Sungmoon Lee, Suwon-si (KR)

(21) Appl. No.: 18/295,867

(22) Filed: Apr. 5, 2023

(30) Foreign Application Priority Data
Jun. 20, 2022 (KR) 10-2022-0075121

(51) Int. Cl. H01L 29/417; H01L 27/088; H01L 29/775; H01L 29/423; H01L 29/06

(52) U.S. Cl. CPC H01L 29/41766; H01L 27/088; H01L 29/775; H01L 29/42392; H01L 29/0673

(57) ABSTRACT

A semiconductor device includes first and second active regions on a substrate and extending in a first direction, first and second gate structures on the first and second active regions, respectively, the first and second gate structures extending in a second direction and being spaced apart from each other in the second direction, first and second source/drain regions on the first and second active regions, respectively, and spaced apart from the first and second gate structures, first and second contact plugs on the first and second source/drain regions and respectively connected to the first and second source/drain regions, and a vertical buried structure between the first and second gate structures and between the first and second source/drain regions. The vertical buried structure may include first and second side surfaces, and the first contact plug contacts the first side surface of the vertical buried structure.

### CROSS-REFERENCE TO RELATED APPLICATION(S)

This application claims priority under 35 U.S.C. § 119 to Korean Patent Application No. 10-2022-0075121 filed on Jun. 20, 2022 in the Korean Intellectual Property Office, the disclosure of which is incorporated herein by reference in its entirety.

### BACKGROUND

The present disclosure relates to semiconductor devices.

As demand for high performance, high speed, and/or multifunctionality in semiconductor devices increases, the degree of integration of semiconductor devices has increased. A semiconductor device with high integration density may include patterns having fine widths or fine spacings therebetween. Moreover, to overcome limitations of operating characteristics caused by a reduction in size of a planar metal oxide semiconductor FET (MOSFET), efforts have been made to develop a semiconductor device including a channel with a three-dimensional structure (e.g., a FinFET).

### SUMMARY

Example embodiments provide a semiconductor device having an increased degree of integration and improved electrical characteristics.

According to an example embodiment, a semiconductor device includes: first and second active regions on a substrate and extending in a first direction; a first gate structure and a second gate structure on the first and second active regions, respectively, the first and second gate structures extending in a second direction and being spaced apart from each other in the second direction; first and second source/drain regions on the first and second active regions, respectively, and adjacent to the first and second gate structures; first and second contact plugs on first and second the source/drain regions and respectively connected to the first and second source/drain regions; and a vertical buried structure between the first and second gate structures and between the first and second source/drain regions. The vertical buried structure may include first and second side surfaces spaced apart from each other in the second direction, and the first contact plug contacts the first side surface of the vertical buried structure.

According to an example embodiment, a semiconductor device includes: first and second active regions on a substrate and extending in a first direction; a first gate structure and a second gate structure on the first and second active regions, respectively, the first and second gate structures extending in a second direction and being spaced apart from each other in the second direction; first and second source/drain regions on the first and second active regions, respectively, and adjacent to the first and second gate structures; first and second contact plugs on the first and second source/drain regions and respectively connected to the first and second source/drain regions; and a vertical buried structure between the first and second source/drain regions. The vertical buried structure may include first and second side surfaces that are spaced apart from each other in the second direction, and the first contact plug contacts the first side surface of the vertical buried structure. The first contact plug may include first and second end portions that are spaced apart from each other in the second direction, and the first end portion of the first contact plug is in the vertical buried structure, in a plan view.

According to an example embodiment, a semiconductor device includes: first and second active regions on a substrate and extending in a first direction; a first gate structure and a second gate structure on the first and second active regions, respectively, the first and second gate structures extending in a second direction and being spaced apart from each other in the second direction; first and second source/drain regions on the first and second active regions, respectively, and adjacent to the first and second gate structures; first and second contact plugs on the first and second source/drain regions and respectively connected to the first and second source/drain regions; a vertical buried structure including first and second side surfaces that are spaced apart from each other in the second direction. The first contact plug contacts an upper portion of the first side surface, and a horizontal buried structure contacting a lower surface of the vertical buried structure. An uppermost end of the vertical buried structure may be on a level farther than an uppermost end of the first source/drain region from the substrate.

### BRIEF DESCRIPTION OF DRAWINGS

The above and other aspects, features, and advantages of the present disclosure will be more clearly understood from the following detailed description, taken in conjunction with the accompanying drawings.

FIGS. 1 1A and 1B are plan views illustrating a semiconductor device according to example embodiments.

FIGS. 2A to 2C are cross-sectional views illustrating a semiconductor device according to example embodiments.

FIGS. 3A and 3B are schematic cross-sectional views illustrating semiconductor devices according to example embodiments.

FIG. 4 is a schematic cross-sectional view illustrating a semiconductor device according to example embodiments.

FIGS. 5A and 5B are schematic cross-sectional views illustrating a semiconductor device according to example embodiments.

FIG. 6 is a plan view illustrating a semiconductor device according to example embodiments.

FIGS. 7A to 7C are cross-sectional views illustrating a semiconductor device according to example embodiments.

FIGS. 8A to 19C are diagrams illustrating a process sequence of a method of fabricating a semiconductor device according to example embodiments.

FIGS. 20A to 20D diagrams illustrating a process sequence of a method of fabricating a semiconductor device according to example embodiments.

### DETAILED DESCRIPTION

Hereinafter, example embodiments will be described with reference to the accompanying drawings.

In the descriptions below, terms “upper,” “upper portion,” “upper surface,” “lower,” “lower portion,” “lower surface,” “side surface,” and the like, are used with reference to the diagrams unless otherwise indicated. Although the terms first, second, and other terms may be used herein to describe various elements, these elements should not be limited by these terms. Those terms are only used to distinguish one element from another. For example, a first element may be referred to as a second element, and, similarly a second element may be referred to as a first element without departing from the teachings of the disclosure. As used herein, an element or region that is “covering” or “surrounding” or “filling” another element or region may completely or partially cover or surround or fill the other element or region.

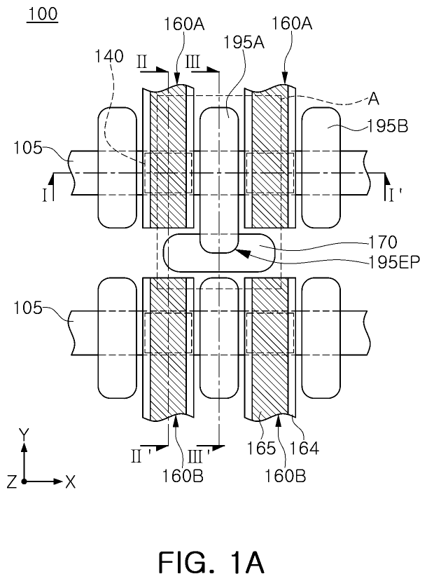

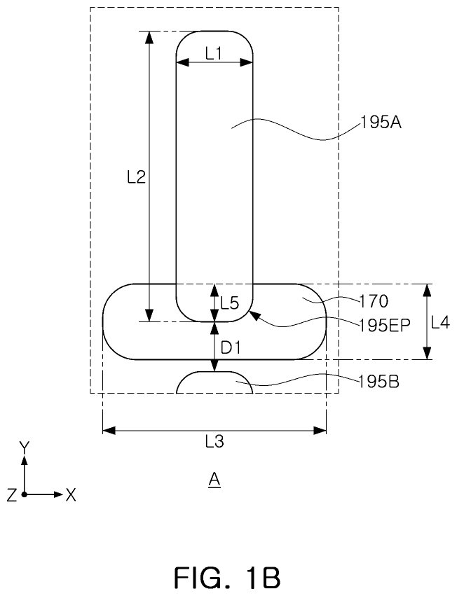

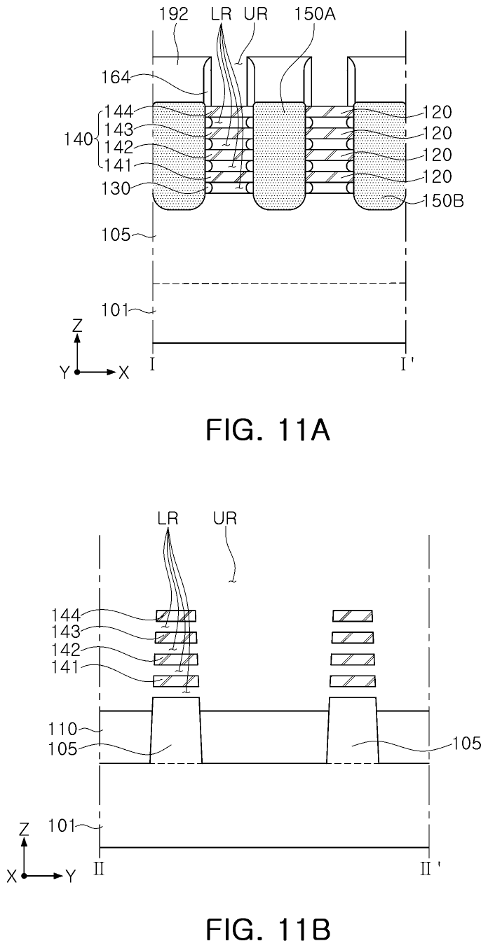

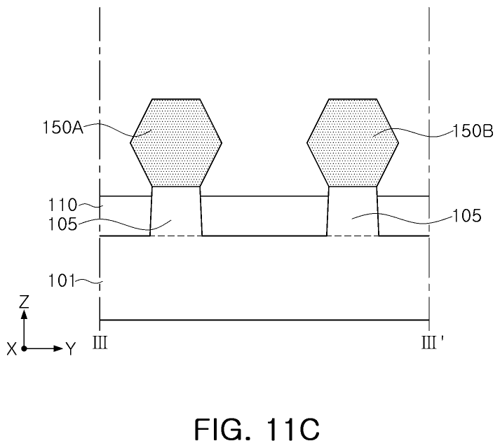

FIGS. 11A and 1B are plan views illustrating a semiconductor device according to example embodiments. FIG. 1B is an enlarged plan view of selected components (e.g., major components) in region “A” of FIG. 1A.

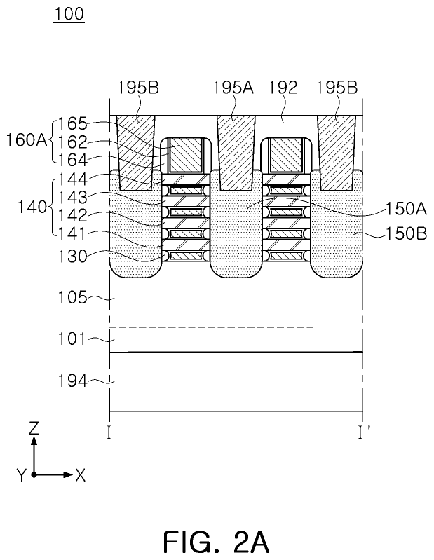

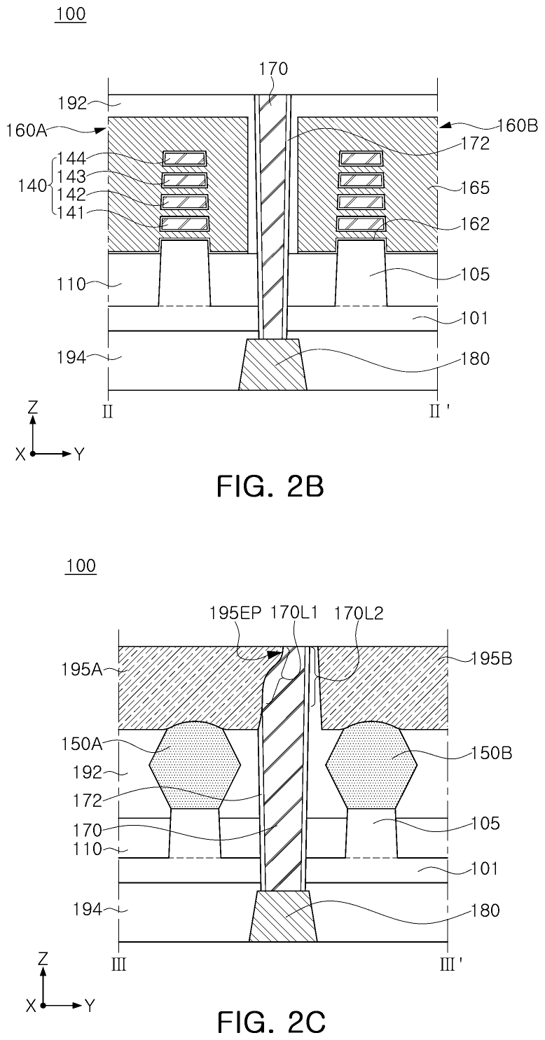

FIGS. 2A, 2B and 2C are cross-sectional views illustrating a semiconductor device according to example embodiments. FIGS. 2A to 2C are cross-sectional views taken along lines I-I′, II-II′, and III-III′ of FIG. 1, respectively. For ease of description, only selected components (e.g., major components) of the semiconductor device are illustrated in FIGS. 1A and 1B.

Referring to FIGS. 1A to 2C, a semiconductor device 100 may include a substrate 101 including active regions 105, channel structures 140 including first to fourth channel layers 141, 142, 143, and 144 vertically spaced apart from each other on the active regions 105, first and second gate structures 160A and 160B extending on (e.g., traversing or intersecting) the active regions 105 and respectively including a gate electrode 165, first and second source/drain regions 150A and 150B contacting the channel structures 140, first and second contact plugs 195A and 195B, respectively connected to the first and second source/drain regions 150A and 150B, and a vertical buried structure 170 connected to the first contact plug 195A. The semiconductor device 100 may further include an isolation layer 110, internal spacer layers 130, a vertical insulating layer 172, a horizontal buried structure 180, and first and second interlayer insulating layers 192 and 194. Each of the first and second gate structures 160A and 160B may include gate dielectric layers 162, gate spacer layers 164, and a gate electrode 165.

In the semiconductor device 100, the gate electrode 165 may be disposed between the active region 105 and the channel structures 140, between the first to fourth channel layers 141, 142, 143, and 144 of the channel structures 140, and on the channel structures 140. Accordingly, the semiconductor device 100 may include transistors having a multi-bridge channel FET (MBCFET™) structure, gate-all-around type field effect transistors.

The substrate 101 may have an upper surface extending in an X-direction (also referred to as a first direction or a first horizontal direction) and a Y-direction (also referred to as a second direction or a second horizontal direction). The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon-on-insulator (SOI) layer, a semiconductor-on-insulator (SeOI) layer, or the like.

The substrate 101 may include active regions 105 disposed thereon. However, the active regions 105 may be described as being separate from the substrate 101, depending on a description method. In some embodiments, the substrate 101 below the active regions 105 may be removed.

The active regions 105 may be disposed to extend in a first direction, for example, an X-direction. The active regions 105 may be defined to a predetermined depth from an upper surface of a portion of the substrate 101. The active regions 105 may be formed as a portion of the substrate 101, or may include an epitaxial layer grown from the substrate 101. Each of the active regions 105 may include active fins protruding upwardly. The active regions 105 may constitute an active structure, in which a channel region of a transistor is formed, together with the channel structures 140. Each of the active regions 105 may include an impurity region. The impurity region may constitute at least a portion of a well region of the transistor. As used herein, “an element A extends in a direction X” (or similar language) may mean that the element A extends longitudinally in the direction X.

The isolation layer 110 may be disposed between adjacent active regions 105 in a Y-direction. Upper surfaces of the active regions 105 may be disposed on a level, higher level than a level of an upper surface of the isolation layer 110. Portions of the active regions 105 may recessed on opposite sides adjacent to the first and second gate structures 160A and 160B, and first and second source/drain regions 150A and 150B may be disposed in the recessed regions, respectively.

The isolation layer 110 may fill a space between the active regions 105, and may define the active regions 105 in the substrate 101. The isolation layer 110 may be formed by, for example, a shallow trench isolation (STI) process. The isolation layer 110 may expose an upper surface of the active region 105, or may expose a portion of the upper surface of the active region 105. The isolation layer 110 may be formed of an insulating material. The isolation layer 110 may include, for example, an oxide, a nitride, or a combination thereof.

The first and second gate structures 160A and 160B may be disposed on the active regions 105 to be on (e.g., to traverse or intersect) the active regions 105 and to extend in a second direction, for example, the Y-direction. Channel regions of transistors may be formed in the active regions 105, intersecting the gate electrode 165 of the first and second gate structures 160A and 160B, and the channel structure 140. The first gate structure 160A and the second gate structure 160B may be disposed in a straight line in the Y-direction, and may be disposed to be spaced apart from each other. The first gate structure 160A and the second gate structure 160B may constitute transistors having different electrical characteristics.

Each of the first and second gate structures 160A and 160B may include gate dielectric layers 162, gate spacer layers 164, and a gate electrode 165. In example embodiments, each of the first and second gate structures 160A and 160B may further include a capping layer on an upper surface of the gate electrode 165. In some embodiments, a portion of the first interlayer insulating layer 192 on the first and second gate structures 160A and 160B may be referred to as a gate capping layer.

The gate dielectric layers 162 may be disposed between the active region 105 and the gate electrode 165 and between the channel structure 140 and the gate electrode 165, and may be disposed to cover at least a portion of surfaces of the gate electrode 165. For example, the gate dielectric layers 162 may be disposed to surround all surfaces, other than the upper surface of the gate electrode 165. The gate dielectric layers 162 may extend between the gate electrode 165 and the gate spacer layers 164, but example embodiments are not limited thereto. The gate dielectric layer 162 may include, for example, an oxide, nitride, or a high-κ dielectric material. The high-κ dielectric material may refer to a dielectric material having a dielectric constant, higher than a dielectric constant of a silicon oxide (SiO₂). The high-κ dielectric material may be, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and/or praseodymium oxide (Pr₂O₃). In some embodiments, the gate dielectric layer 162 may have a multilayer structure.

The gate electrode 165 may include a conductive material, for example, metal nitride such as titanium nitride (TiN), tantalum nitride (TaN), and/or tungsten nitride (WN), metal such as aluminum (Al), tungsten (W), and/or molybdenum (Mo), and/or a semiconductor material such as doped polysilicon. In some embodiments, the gate electrode 165 may have a multilayer structure.

The gate spacer layers 164 may be disposed on opposite side surfaces of the gate electrode 165 on the channel structure 140. The gate spacer layers 164 may insulate the source/drain regions 150 from the gate electrode 165. According to example embodiments, a shape of upper ends of the gate spacer layers 164 may be variously changed and the gate spacer layers 164 may have a multilayer structure. The gate spacer layers 164 may be formed of, for example, an oxide, a nitride, an oxynitride, and/or a low-κ dielectric material. In some embodiments, the gate spacer layers 164 may be a low-κ dielectric material. As used herein the term “and/or” includes any and all combinations of one or more of the associated listed items.

In some embodiments, the first gate structure 160A and the second gate structure 160B may include different materials of the gate electrodes 165 or may have different lengths of the gate electrodes 165 in the X-direction.

The channel structures 140 may be disposed on the active regions 105, in regions in which the active regions 105 intersect the first and second gate structures 160A, 160B. Each of the channel structures 140 may include first to fourth channel layers 141, 142, 143, and 144, two or more channel layers disposed to be spaced apart from each other in a Z-direction (also referred to as a third direction or a vertical direction). The channel structures 140 may be connected to the first and second source/drain regions 150A and 150B. The channel structures 140 may have a width, equal to or smaller than a width of the active region 105 in the Y-direction, and may have a width, equal to or similar to a width of the first and second gate structures 160A and 160B in the X-direction. In a cross-section in the Y-direction, among the first to fourth channel layers 141, 142, 143, and 144, a channel layer disposed in a lower portion may have a width, equal to or greater than a width of a channel layer disposed in an upper portion. In some embodiments, the first and second gate structures 160A and 160B may have reduced widths, as compared with widths of the first and second gate structures 160A and 160B, such that side surfaces of the channel structures 140 are disposed below the first and second gate structures 160A and 160B.

The channel structures 140 may be formed of, for example, a semiconductor material, and may include at least one of, for example, silicon (Si), silicon-germanium (SiGe), and germanium (Ge). The channel structures 140 may be formed of, for example, the same material as the active regions 105. The number and shape of the channel layers, constituting a single channel structure 140, may vary according to example embodiments.

The first and second source/drain regions 150A and 150B may be disposed to contact the channel structures 140 on opposite sides adjacent to the first and second gate structures 160A and 160B, respectively. The first and second source/drain regions 150A and 150B may be disposed in regions in which an upper portion of the active region 105 is partially recessed. The first source/drain region 150A may refer to a source/drain region connected to the vertical buried structure 170 through the first contact plug 195A, and the second source/drain regions 150B may refer to the other source/drain regions. The first source/drain region 150A may be electrically connected to the horizontal buried structure 180 through the first contact plug 195A and the vertical buried structure 170 to be applied with power.

Upper surfaces of the first and second source/drain regions 150A and 150B may be disposed on a level the same as or similar to a level of lower surfaces of the first and second gate structures 160A and 160B on the channel structures 140. However, the level of the upper surfaces of the first and second source/drain regions 150A and 150B may vary according to example embodiments. The first and second source/drain regions 150A and 150B may have, for example, a polygonal shape, an elliptical shape, or the like, in a cross-section in the Y-direction, as illustrated in FIG. 2C, but example embodiments are not limited thereto. The first and second source/drain regions 150A and 150B may include a semiconductor material, for example, silicon (Si) and/or germanium (Ge), and may further include impurities.

The inner spacer layers 130 may be disposed side by side with the gate electrode 165 between the first to fourth channel layers 141, 142, 143, and 144 in the Z-direction. The gate electrode 165 may be stably spaced apart from the first and second source/drain regions 150A and 150B by the internal spacer layers 130 to be electrically separated therefrom. The internal spacer layers 130 may have a shape in which a side surface, facing the gate electrode 165, is convexly rounded inwardly of the gate electrode 165, but example embodiments are not limited thereto. The internal spacer layers 130 may include, for example, an oxide, a nitride, and an oxynitride, and/or a low-κ dielectric material. In some embodiments, the internal spacer layers 130 may be formed of a low-κ dielectric material. However, in some embodiments, the internal spacer layers 130 may be omitted.

The first and second contact plugs 195A and 195B may be disposed on the first and second source/drain regions 150A and 150B. The first contact plugs 195A may penetrate through the first interlayer insulating layer 192 to be connected to the first source/drain regions 150A, and the second contact plugs 195B may penetrate through the first interlayer insulating layer 192 to be connected to the second source/drain regions 150B.

As illustrated in FIG. 1A, the first contact plug 195A may be disposed to protrude to a region, in which the first and second gate structures 160A and 160B are not disposed, in the Y-direction. The first contact plug 195A may protrude to a region, in which the first gate structure 160A and the second gate structure 160B are spaced apart from each other in the Z-direction, or a region overlapping the region in the X-direction. The first contact plug 195A may be connected to the vertical buried structure 170 in the region. As illustrated in FIG. 1B, the first contact plug 195A may have a first length L1 in the X-direction and a second length L2, greater than the first length L1, in the Y-direction. In FIG. 1A, the first contact plug 195A is illustrated as having a length, greater than a length of second contact plugs 195B in the Y-direction, but relative lengths of the first and second contact plugs 195A and 195B are not limited thereto. A distance D1 between the first contact plug 195A and the adjacent second contact plug 195B in the Y-direction may be within a range of, for example, about 20 nanometers (nm) to about 30 nm.

A region of the first contact plug 195A may be disposed on the vertical buried structure 170. Among side surfaces of the first contact plug 195A in the Y-direction, a side surface directed toward the vertical buried structure 170 may be disposed on the vertical buried structure 170. In the first contact plug 195A, an end portion 195EP connected to the vertical buried structure 170 may be disposed to overlap the vertical buried structure 170 in a plan view, as illustrated in FIG. 1A. In some embodiments, an upper portion of the first contact plug 195A (e.g., the end portion 195EP) may overlap a lower portion of the vertical buried structure 170 in the Z-direction, as illustrated in FIG. 2C. A region of the first contact plug 195A, including the end portion 195EP, may overlap the vertical buried structure 170 in the Z-direction. The end portion 195EP may be surrounded by the vertical buried structure 170 in a plan view. A region of the first contact plug 195A, including the end 195EP, may also overlap the vertical buried structure 170 in the X-direction and the Y-direction. The first contact plug 195A may have a side surface including irregular curved surfaces having a plurality of curvatures in the end portion 195EP contacting the vertical buried structure 170, as illustrated in FIG. 2C. However, a detailed shape of the side surface may vary according to example embodiments.

Each of the first and second contact plugs 195A and 195B may have a side surface inclined to have a width (e.g., a width in the X-direction or the Y-direction) decreasing in a direction toward the substrate 101 due to an aspect ratio, but example embodiments are not limited thereto. The first and second contact plugs 195A and 195B may be disposed to contact portions of the upper surfaces and the inclined surfaces of the first and second source/drain regions 150A and 150B by recessing portions of the first and second source/drain regions 150A and 150B. In some embodiments, the first and second contact plugs 195A and 195B may be disposed to contact the upper surfaces of the first and second source/drain regions 150A and 150B without recessing the first and second source/drain regions 150A and 150B. Additional gate contact plugs may be further disposed on the gate electrodes 165 in a region, not illustrated.

Each of the first and second contact plugs 195A and 195B may include a metal silicide layer disposed on a lower end thereof, and may further include a barrier layer disposed on the metal silicide layer and sidewalls thereof. The barrier layer may include, for example, a metal nitride such as a titanium nitride (TiN), a tantalum nitride (TaN), or a tungsten nitride (WN). The first and second contact plugs 195A and 195B may include, for example, a metal material such as aluminum (Al), tungsten (W), and/or molybdenum (Mo). The number and disposition form of conductive layers, constituting the first and second contact plugs 195A and 195B, may vary according to example embodiments.

The vertical buried structure 170 may be disposed to connect the first contact plug 195A and the horizontal buried structure 180 to each other. The vertical buried structure 170 may be disposed to be spaced apart from the first and second gate structures 160A and 160B in the Y-direction. As illustrated in FIGS. 1A and 1B, the vertical buried structure 170 may be formed in a region, in which the first gate structure 160A and the second gate structure 160B are spaced apart from each other in the Y-direction, and/or a region overlapping the region in the X-direction. Accordingly, the vertical buried structure 170 may not overlap the first and second gate structures 160A and 160B in the X-direction.

As illustrated in FIG. 1B, the vertical buried structure 170 may have a third length L3 in the X-direction and a fourth length L4, smaller than the third length L3, in the Y-direction. The fourth length L4 may be with a range of, for example, about 10 nm to about 40 nm, in detail, a range of about 20 nm to about 30 nm. In some embodiments, the vertical buried structure 170 may have a circular shape in a plan view. The length L5 of the region, in which the vertical buried structure 170 overlaps the first contact plug 195A in the Y-direction in a plan view, may vary within a range in which the end 195EP is disposed on the vertical buried structure 170.

In the present embodiment, an upper surface of the vertical buried structure 170 may be disposed on substantially the same level as upper surfaces of the first and second contact plugs 195A and 195B. The substrate 101 is equidistant from an uppermost end of the vertical buried structure 170 and an uppermost end of the first and second contact plugs 195A and 195B. The upper surface or an upper end of the vertical buried structure 170 may be disposed on a level, higher than levels of upper surfaces or upper ends of the first and second source/drain regions 150A and 150B. An uppermost end of the vertical buried structure 170 is farther than an uppermost end of the first and second source/drain regions 150A and 150B from the substrate 101. A lower surface of the vertical buried structure 170 may be disposed on a level, lower than a level of lower surfaces of the first and second source/drain regions 150A and 150B, and may be disposed on a level, lower than levels of upper and lower surfaces of the active regions 105. A lowermost end of the vertical buried structure 170 is closer than a lowermost end of the first and second source/drain regions 150A and 150B to a bottom of the substrate 101. The vertical buried structure 170 may have a side surface inclined to have a width decreasing in a direction toward the substrate 101 due to an aspect ratio, but example embodiments are not limited thereto. In the vertical buried structure 170, a width in the Y-direction to a height in the Z-direction may be within a range of, for example, about 1:2 to 1:10, in detail, about 1:3 to 1:8. As used herein, “a level V is higher than a level W” (or similar language) may mean that the level V is farther than the level V to the substrate 101.

The vertical buried structure 170 may be disposed between the first source/drain region 150A and the second source/drain region 150B adjacent to each other in the Y-direction, as illustrated in FIG. 2C. The vertical buried structure 170 may be disposed to contact the first contact plug 195A through a first upper side surface 170L1, an upper region of one side surface. The first upper surface 170L1 may have an asymmetric shape with an opposing second upper surface 170L2, and may include regions having different degrees of inclination. The second upper surface 170L2 may be inclined at an angle, almost vertical to the upper surface of the substrate 101, as compared with the first upper surface 170L1. The first upper surface 170L1 may have a shape formed by partially removing or recessing the first upper surface 170L1 from an upper portion thereof. The first upper surface 170L1 may have an inclination such that a position of an upper end thereof is lowered in a direction toward the first source/drain region 150A. The inclination is not a straight line but may include a plurality of curves, but example embodiments are not limited thereto. Accordingly, the vertical buried structure 170 (e.g., an upper portion of the vertical buried structure 170) may have an asymmetrical shape with respect to a center in a cross-section in the Y-direction. In some embodiments, the vertical buried structure 170 has a center point in the Y-direction and has an asymmetric shape with respect to an imaginary line that extending through the center point in the Z-direction.

The vertical buried structure 170 may be disposed to be spaced apart from an adjacent second contact plug 195B by the first interlayer insulating layer 192 and the vertical insulating layer 172, and may be electrically separated from the adjacent second contact plug 195B. The vertical buried structure 170 may include a conductive material, for example, a metal material such as molybdenum (Mo), aluminum (Al), or tungsten (W).

Since the vertical buried structure 170 is disposed to contact the first contact plug 195A through a side surface thereof, a contact area may be secured and a length of the first contact plug 195A in the Y-direction may be significantly reduced, as compared with a case in which the vertical buried structure 170 contacts the first contact plug 195A through only the upper surface thereof. Accordingly, a distance between the first gate structure 160A and the second gate structure 160B may also be significantly reduced to further increase a degree of integration of the semiconductor device 100.

The vertical insulating layer 172 may be disposed to cover side surfaces of the vertical buried structure 170. In a region in which the vertical insulating layer 172 contacts the first contact plug 195A, the vertical insulating layer 172 may be partially removed from an upper portion thereof to expose the vertical buried structure 170. The vertical insulating layer 172 may include an insulating material, for example, at least one of an oxide, a nitride, and an oxynitride.

The horizontal buried structure 180 may be connected to the lower end or the lower surface of the vertical buried structure 170. The horizontal buried structure 180 may constitute a backside power delivery network (BSPDN) applying power or a ground voltage, and may be referred to as a buried power rail. For example, the horizontal buried structure 180 may be a buried interconnection line extending from a bottom of the vertical buried structure 170 in one direction, for example, the X-direction, but a shape of the horizontal buried structure 180 is not limited thereto. The horizontal buried structure 180 may be further connected to a vertical buried structure 170, not illustrated, in a region, not illustrated.

Side surfaces of the horizontal buried structure 180 may be covered with a second interlayer insulating layer 194. The horizontal buried structure 180 may have side surfaces inclined to have a width decreasing in an upward direction. The horizontal buried structure 180 may be formed of a conductive material such as at least one of tungsten (W), copper (Cu), aluminum (Al), cobalt (Co), ruthenium (Ru), titanium (Ti), or molybdenum (Mo).

The first interlayer insulating layer 192 may be disposed to cover upper surfaces of the first and second source/drain regions 150A and 150B and the first and second gate structures 160A and 160B and an upper surface of the isolation layer 110. The second interlayer insulating layer 194 may be disposed to cover the lower surface of the substrate 101 and to surround the horizontal buried structure 180.

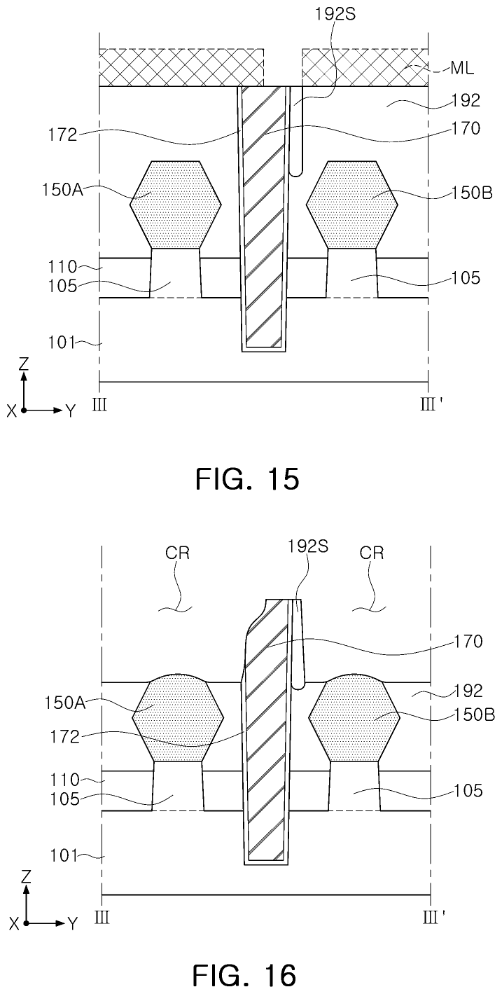

The first and second interlayer insulating layers 192 and 194 may include, for example, an oxide, a nitride, and an oxynitride, and/or a low-κ dielectric material. In example embodiments, each of the first and second interlayer insulating layers 192 and 194 may include a plurality of insulating layers. For example, in the first interlayer insulating layer 192, a nitride layer corresponding to an upper insulating layer 192S to be described below with reference to FIG. 15 may be disposed in a region between the vertical buried structure 170 and the second contact plug 195B, and an oxide layer may be disposed in the other regions.

The semiconductor device 100 may be packaged by inverting the structure of FIGS. 2A to 2C such that the horizontal buried structure 180 is disposed in an upper portion, but a packaging form of the semiconductor device 100 is not limited thereto. Since the semiconductor device 100 includes the horizontal buried structure 180 disposed below the first and second source/drain regions 150A and 150B, the degree of integration of the semiconductor device 100 may be increased. In addition, since the vertical buried structure 170 is disposed to be connected to the first contact plug 195A through the side surface thereof, contact resistance may be significantly reduced and a distance between the first gate structure 160A and the second gate structure 160B may be significantly reduced, so that the degree of integration of the semiconductor device 100 may be further increased.

In the descriptions of example embodiments below, descriptions overlapping the descriptions provided with reference to FIGS. 1A to 2C will be omitted.

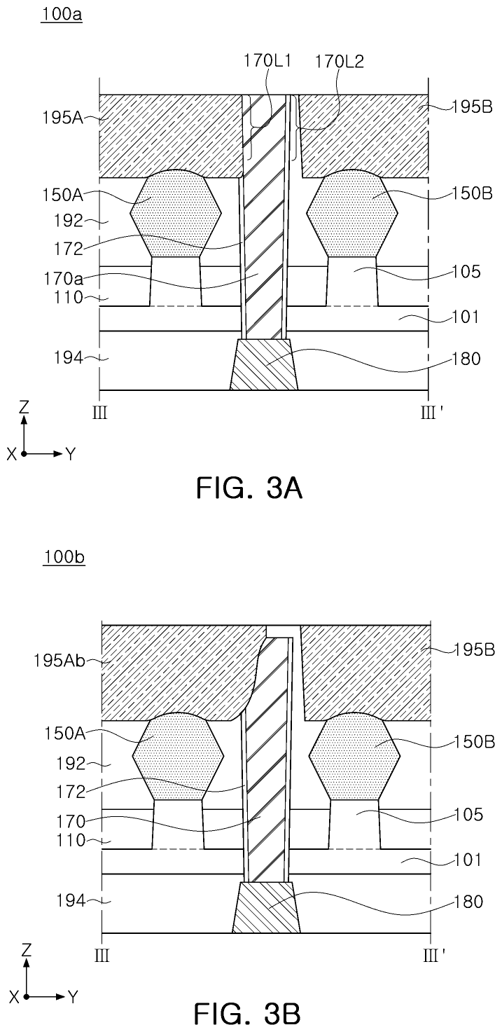

FIGS. 3A and 3B are schematic cross-sectional views illustrating semiconductor devices according to example embodiments. FIGS. 3A and 3B illustrate a region corresponding to FIG. 2C.

Referring to FIG. 3A, in a vertical buried structure 170a of a semiconductor device 100a, a shape of a first upper surface 170L1 contacting a first contact plug 195A may be different from that in the example embodiment of FIG. 2C.

The first upper side surface 170L1 may be substantially symmetrical to an opposing second upper surface 170L2, and may have inclination the same as or similar to inclination of the second upper surface 170L2. The first and second upper surfaces 170L1 and 170L2 may have the same lateral inclination depending on an aspect ratio of the vertical buried structure 170a. Accordingly, the vertical buried structure 170 may be symmetrical with respect to a center in a cross-section in a Y-direction. As described above, a degree at which the vertical buried structures 170 and 170a are removed from the upper surface and a shape of the first upper surface 170L1 depending on the degree may vary according to example embodiments.

In the present embodiment, the vertical insulating layer 172 may also be partially removed from an upper portion thereof to expose the vertical buried structure 170a in a region in which the vertical insulating layer 172 contacts the first contact plug 195A.

Referring to FIG. 3B, in a semiconductor device 100b, a first contact plug 195Ab may contact a portion of a side surface and a portion of an upper surface of a vertical buried structure 170. The first contact plug 195Ab may contact a portion of a horizontal upper surface of the vertical buried structure 170. The first contact plug 195Ab may be disposed on an upper surface of the vertical buried structure 170 to have a predetermined thickness. In the present embodiment, a level of the upper surface of the first contact plug 195Ab may be higher than a level of an upper surface of the vertical buried structure 170. In example embodiments, a length of a region, in which the first contact plug 195Ab contacts the upper surface of the vertical buried structure 170, may vary according to example embodiments. A shape of the first contact plug 195Ab in the present embodiment may also be applied to other embodiments.

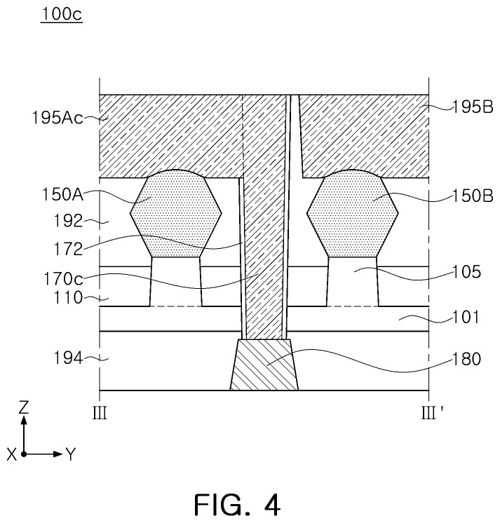

FIG. 4 is a schematic cross-sectional view illustrating a semiconductor device according to example embodiments. FIG. 4 illustrates a region corresponding to FIG. 2C.

Referring to FIG. 4, in a semiconductor device 100c, a vertical buried structure 170c may be formed to be integrated with a first contact plug 195Ac. The first contact plug 195Ac and the vertical buried structure 170c may include a single conductive layer. The conductive layer may be formed of, for example, the same material as a second contact plugs 195B. As described above, a form in which the vertical buried structure 170c and the first contact plug 195Ac are formed to be integrated with each other may be applied to other embodiments.

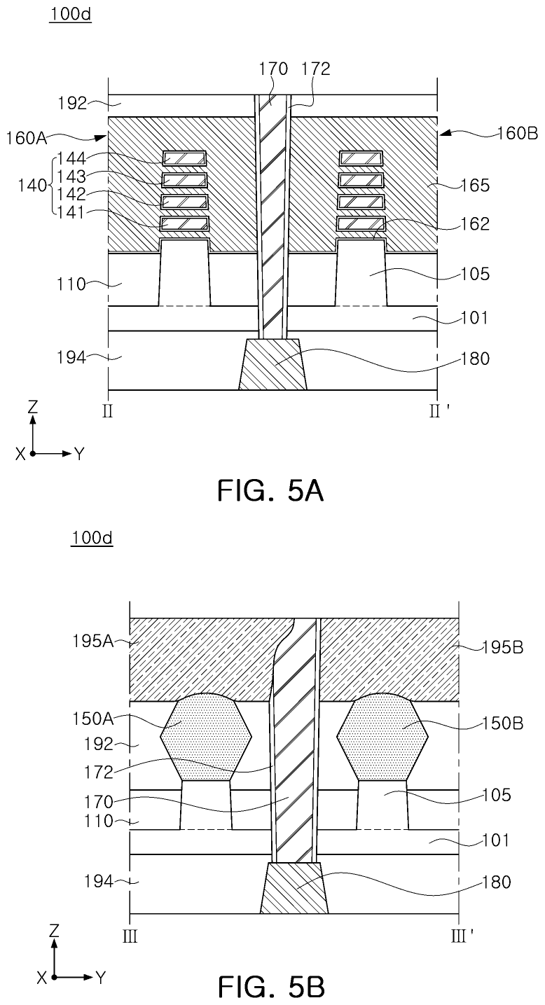

FIGS. 5A and 5B are schematic cross-sectional views illustrating semiconductor devices according to example embodiments. FIG. 5A illustrates a region corresponding to FIG. 2B, and FIG. 5B illustrates a region corresponding to FIG. 2C.

Referring to FIGS. 5A and 5B, in a semiconductor device 100d, a first interlayer insulating layer 192 may not be disposed on an outside of a vertical buried structure 170. The vertical buried structure 170 may be electrically separated from gate electrodes 165 of first and second gate structures 160A and 160B by a vertical insulating layer 172. Also, the vertical buried structure 170 may be electrically separated from an adjacent second source/drain regions 150B and an adjacent second contact plug 195B by the vertical insulating layer 172.

As described above, the present embodiment may be applied to other embodiments, and a disposition and a thickness of the first interlayer insulating layer 192 on the outside of the vertical buried structure 170 may vary according to example embodiments.

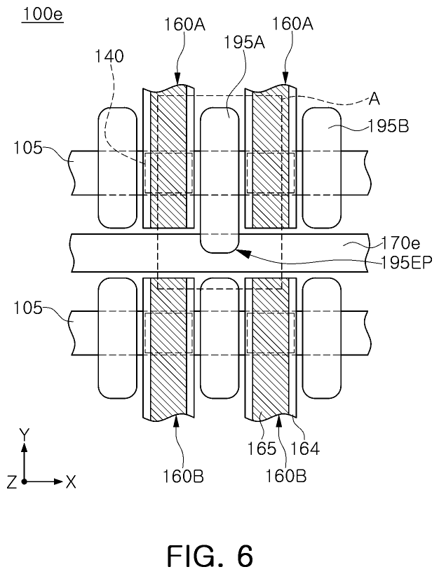

FIG. 6 is a plan view illustrating a semiconductor device according to example embodiments. FIG. 6 illustrates a plane corresponding to FIG. 1A.

Referring to FIG. 6, in a semiconductor device 100e, a vertical buried structure 170e may have a line shape extending in an X-direction. The vertical buried structure 170e may extend between, for example, a plurality of first gate structures 160A and a plurality of second gate structures 160B. However, a length of the vertical buried structure 170e in the X-direction may vary according to example embodiments.

In the present embodiment, a horizontal buried structure 180 (see FIG. 2C) may be disposed to extend in various directions. In some embodiments, a column-shaped via structure may be further disposed between the vertical buried structure 170e and the horizontal buried structure 180.

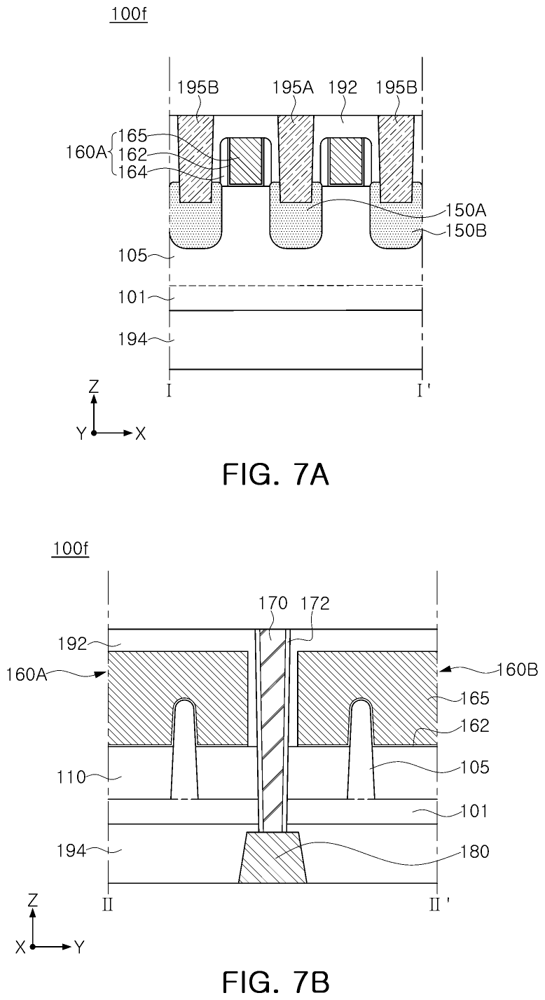

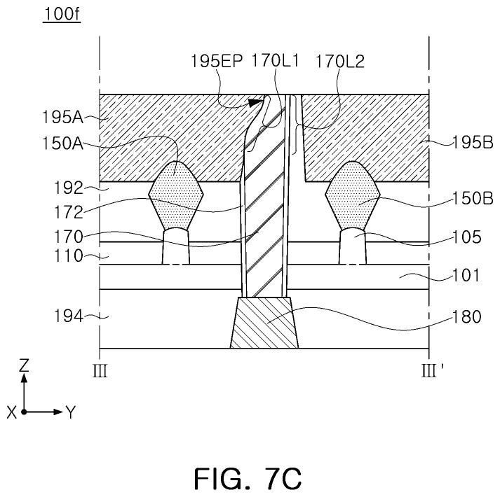

FIGS. 7A to 7C are cross-sectional views illustrating a semiconductor device according to example embodiments. FIGS. 7A to 7C illustrate cross-sections corresponding to FIGS. 2A to 2C, respectively.

Referring to FIGS. 7A to 7C, a semiconductor device 100f may not include a channel structures 140, unlike the semiconductor device 100 according to example embodiment of FIGS. 1A to 2C. Therefore, dispositions of first and second gate structures 160A and 160B may be different from those in the above-described example embodiment. The semiconductor device 100f may include FinFETs which do not include an additional channel layer.

In the semiconductor device 100f, a channel region of transistors may be limited to active regions 105 having a fin structure, an active structure. Also, additional channel layers may not be interposed in the gate electrodes 165. However, other descriptions of the gate electrodes 165 and the description of the vertical buried structure 170 may be equally applied to the descriptions in the example embodiments of FIGS. 1 to 2C. The semiconductor device 100f may be equally applied to other embodiments or may be additionally disposed in a region of a semiconductor device according to other embodiments.

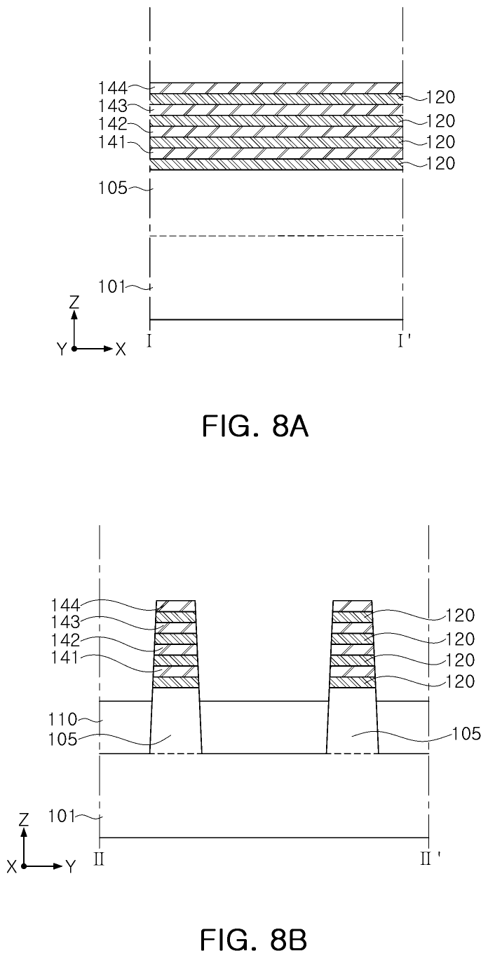

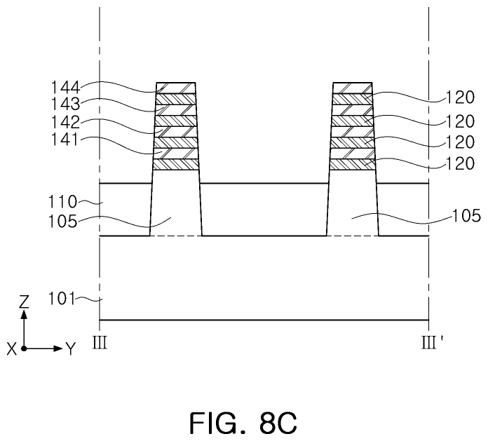

FIGS. 8A to 19C are diagrams illustrating a method of fabricating a semiconductor device according to example embodiments. In some embodiments, operations illustrated in FIGS. 8A to 19C may be performed sequentially. In FIGS. 8A to 19C, an example embodiment of a method of fabricating the semiconductor device of FIGS. 1A to 2C is illustrated. FIGS. 8A, 9A, 10A, 11A, 12A, 13A, and 19A illustrate cross-sections corresponding to FIG. 2A, FIGS. 8B, 9B, 10B, 11B, 12B, 13B, and 19B illustrate cross-sections corresponding to FIG. 2B, and FIGS. 8C, 9C, 10C, 11C, 12C, 13C to 18, and 19C illustrate cross-sections corresponding to FIG. 2C.

Referring to FIGS. 8A to 8C, sacrificial layers 120 and first to fourth channel layers 141, 142, 143, and 144 may be alternately stacked on a substrate 101, and an active structure including active regions 105 may be formed.

The sacrificial layers 120 may be replaced with gate dielectric layers 162 and the gate electrode 165 below the fourth channel layer 144 through a subsequent process, as illustrated in FIGS. 2A and 2B. The sacrificial layers 120 may be formed of a material having etching selectivity with respect to each of the first to fourth channel layers 141, 142, 143, and 144. The first to fourth channel layers 141, 142, 143, and 144 may include a material, different from a material of the sacrificial layers 120. The sacrificial layers 120 and the first to fourth channel layers 141, 142, 143, and 144 may include a semiconductor material including at least one of, for example, silicon (Si), silicon-germanium (SiGe), and germanium (Ge) but may include different materials, and may or may not include impurities. For example, the sacrificial layers 120 may include silicon-germanium (SiGe), and the first to fourth channel layers 141, 142, 143, and 144 may include silicon (Si).

The sacrificial layers 120 and the first to fourth channel layers 141, 142, 143, and 144 may be formed by performing an epitaxial growth process from the substrate 101. Each of the sacrificial layers 120 and the first to fourth channel layers 141, 142, 143, and 144 may have a thickness ranging from about 1 angstrom (Å) to about 100 nanometers (nm). The number of the channel layers 141, 142, 143, and 144, stacked alternately with the sacrificial layers 120, may vary according to example embodiments.

Then, the sacrificial layers 120, the first to fourth channel layers 141, 142, 143, and 144, and an upper region of the substrate 101 may be patterned to form active structures. The active structures may include sacrificial layers 120 and first to fourth channel layers 141, 142, 143, and 144 alternately stacked, and may further include active regions 105 formed to protrude from the substrate 101 (e.g., an upper surface or a top surface of the substrate 101) by removing a portion of the substrate 101. The active structures may be formed in a line shape extending in one direction, for example, an X-direction, and may be formed to be spaced apart from each other in a Y-direction. Side surfaces of the active structures may be downwardly inclined to increase a width depending on an aspect ratio.

An isolation layer 110 may be formed by filling a region, in which a portion of the substrate 101 is removed, with an insulating material and then removing a portion of the insulating material such that the active regions 105 protrude from the substrate 101 (e.g., an upper surface or a top surface of the substrate 101). An upper surface of the isolation layer 110 may be formed to be lower than upper surfaces of the active regions 105.

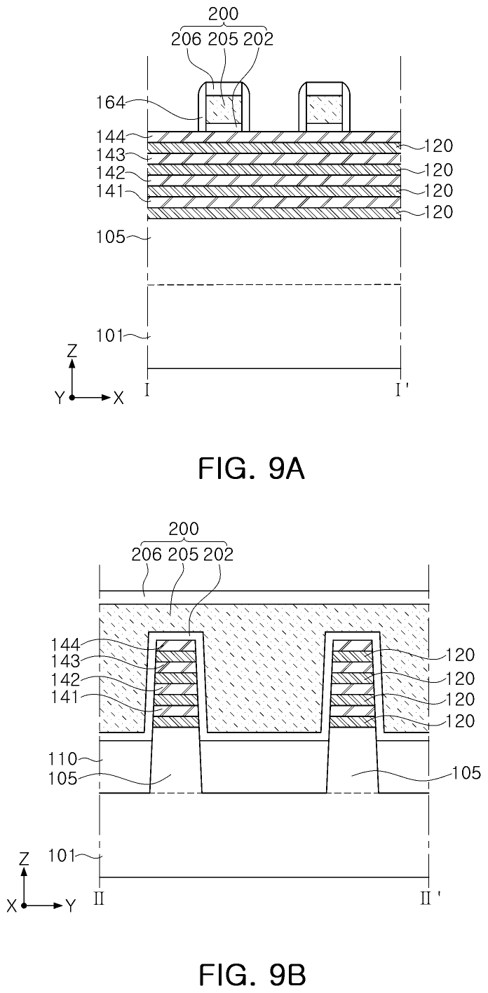

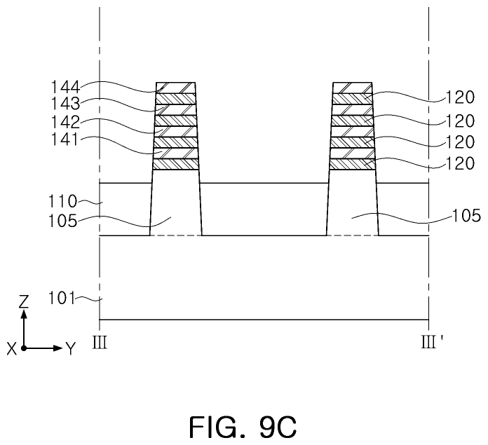

Referring to FIGS. 9A to 9C, a sacrificial gate structure 200 and gate spacer layers 164 may be formed on the active structures.

The sacrificial gate structures 200 may be sacrificial structures formed in a region, in which the gate dielectric layer 162 and the gate electrode 165 are disposed, on the channel structures 140, through a subsequent process, as illustrated in FIGS. 2A and 2B. The sacrificial gate structures 200 may have a line shape extending on (e.g., traversing or intersecting) the active structures and extending in one direction. The sacrificial gate structures 200 may extend in, for example, a Y-direction and may be disposed to be spaced apart from each other in an X-direction.

The sacrificial gate structure 200 may include first and second sacrificial gate layers 202 and 205 and a mask pattern layer 206 stacked in order. The first and second sacrificial gate layers 202 and 205 may be patterned using a mask pattern layer 206. The first and second sacrificial gate layers 202 and 205 may be an insulating layer and a conductive layer, respectively. However, example embodiments are not limited thereto, and the first and second sacrificial gate layers 202 and 205 may be provided as a single layer. For example, the first sacrificial gate layer 202 may include a silicon oxide, and the second sacrificial gate layer 205 may include polysilicon. The mask pattern layer 206 may include a silicon oxide and/or a silicon nitride.

Gate spacer layers 164 may be formed on both sidewalls of the sacrificial gate structures 200. The gate spacer layers 164 may be formed of, for example, a low-κ dielectric material, and, in some embodiments, may include, for example, SiO, SiN, SiCN, SiOC, SiON, SiOCN, and/or a low-κ dielectric material.

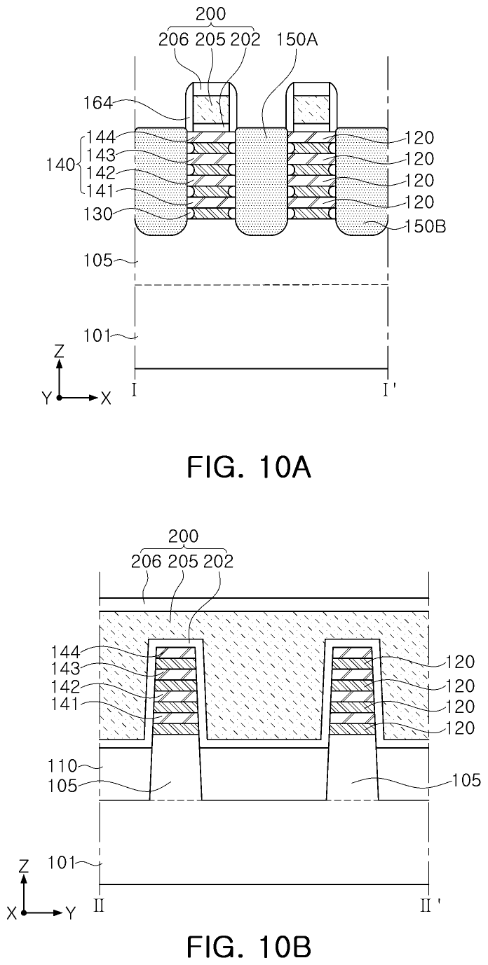

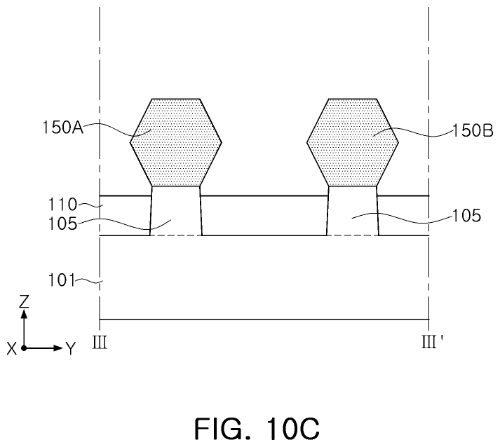

Referring to FIGS. 10A to 10C, the exposed sacrificial layers 120 and the first to fourth channel layers 141, 142, 143, and 144 may be partially removed and internal spacer layers 130 and first and second source/drain regions 150A and 150B may be formed, between the sacrificial gate structures 200.

The exposed sacrificial layers 120 and the first to fourth channel layers 141, 142, 143, and 144 may be partially removed using the sacrificial gate structures 200 and the gate spacer layers 164 as masks to form recess regions. In the present operation, the first to fourth channel layers 141, 142, 143, and 144 may constitute channel structures 140 having a length limited in an X-direction.

Then, a portion of the sacrificial layers 120 exposed through the recess regions may be removed from side surfaces thereof. The sacrificial layers 120 may be selectively etched with respect to the channel structures 140 by, for example, a wet etching process to be removed from the side surfaces to a predetermined depth in the X-direction. The sacrificial layers 120 may have inwardly concave side surfaces through the above-described lateral etching. However, a shape of the side surfaces of the sacrificial layers 120 is not limited to that illustrated in the drawings.

The internal spacer layers 130 may be formed by filling a region, in which the sacrificial layers 120 are removed, with an insulating material and then removing the insulating material deposited on an outside of the channel structures 140. The internal spacer layers 130 may be formed of the same material as the gate spacer layers 164, but example embodiments are not limited thereto. For example, the internal spacer layers 130 may include SiN, SiCN, SiOCN, SiBCN, and/or SiBN.

First and second source/drain regions 150A and 150B may be grown to be formed from the side surfaces of the active regions 105 and the channel structures 140 by, for example, a selective epitaxial process. The first and second source/drain regions 150A and 150B may include impurities through in-situ doping, and may include a plurality of layers having different doping elements and/or doping concentrations.

Referring to FIGS. 11A to 11C, a first interlayer insulating layer 192 may be formed, and the sacrificial layers 120 and the sacrificial gate structures 200 may be removed.

The first interlayer insulating layer 192 may be formed by forming an insulating layer to cover the sacrificial gate structures 200 and the first and second source/drain regions 150A and 150B and then performing a planarization process.

The sacrificial layers 120 and the sacrificial gate structures 200 may be selectively removed with respect to the gate spacer layers 164, the first interlayer insulating layer 192, the channel structures 140, and the inner spacer layers 130. The sacrificial gate structures 200 may be removed to form upper gap regions UR, and the sacrificial layers 120 exposed through the upper gap regions UR may then be removed to form lower gap regions LR. During the removal process, the first and second source/drain regions 150A and 150B may be protected by the first interlayer insulating layer 192 and the internal spacer layers 130.

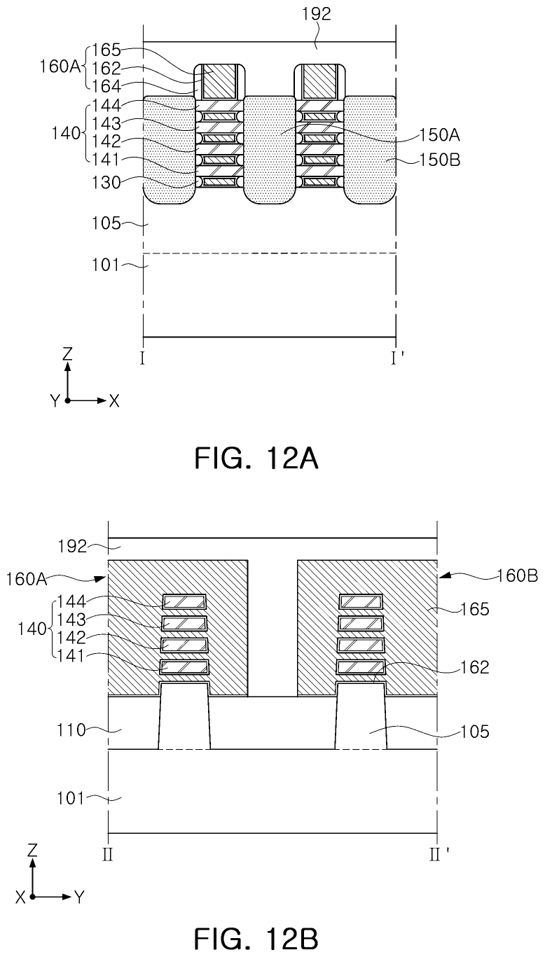

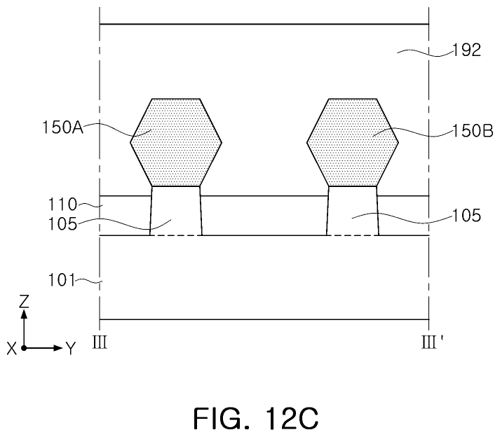

Referring to FIGS. 12A to 12C, a gate dielectric layers 162 and a gate electrode 165 may be formed to form first and second gate structures 160A and 160B.

The gate dielectric layers 162 and the gate electrode 165 may be formed to fill the upper gap regions UR and the lower gap regions LR. The gate dielectric layers 162 may be formed to conformally cover internal surfaces of the upper gap regions UR and the lower gap regions LR. The gate electrode 165 may be formed to completely fill the upper gap regions UR and the lower gap regions LR, and may then be removed to a predetermined depth from an upper portion thereof in the upper gap regions UR together with the gate dielectric layers 162 and the gate spacer layers 164.

The gate dielectric layers 162, the gate electrode 165, and the gate spacer layers 164 may be formed to continuously extend in a Y-direction, and may then be removed in a region by an etching process. Thus, the first and second gate structures 160A and 160B may be formed to be separated from each other in the Y-direction. In some embodiments, only the gate electrode 165 or only the gate dielectric layers 162 and the gate electrode 165 may be removed in the region during the removal process.

A first interlayer insulating layer 192 may be further formed on the first and second gate structures 160A and 160B. The first interlayer insulating layer 192 may fill a region between the first gate structure 160A and the second gate structure 160B.

Referring to FIGS. 13A to 13C, a vertical buried structure 170 and a vertical insulating layer 172 may be formed.

The vertical buried structure 170 may be formed in a region spaced apart from the first gate structure 160A and the second gate structure 160B in the Y-direction. The vertical buried structure 170 may be formed in a region between the first source/drain region 150A and the second source/drain region 150B adjacent to each other in the Y-direction. In the region, a hole may be formed to extend inwardly of the substrate 101 through the first interlayer insulating layer 192, and an insulating layer and a conductive layer may then be sequentially formed in the hole to form the vertical insulating layer 172 and the vertical buried structure 170. The vertical insulating layer 172 may be formed to conformally cover a bottom surface and internal surfaces of the hole, and the vertical buried structure 170 may be formed to fill the hole.

In some embodiments, similarly to the example embodiments of FIGS. 5A to 6, the first interlayer insulating layer 192 may not be additionally formed between the first gate structure 160A and the second gate structure 160B in the operation described above with reference to FIGS. 12A to 12C, but the vertical insulating layer 172 and the vertical buried structure 170 may be formed in the present operation to fabricate the semiconductor device. However, the fabrication method according to the example embodiments of FIGS. 5A to 6 is not limited thereto.

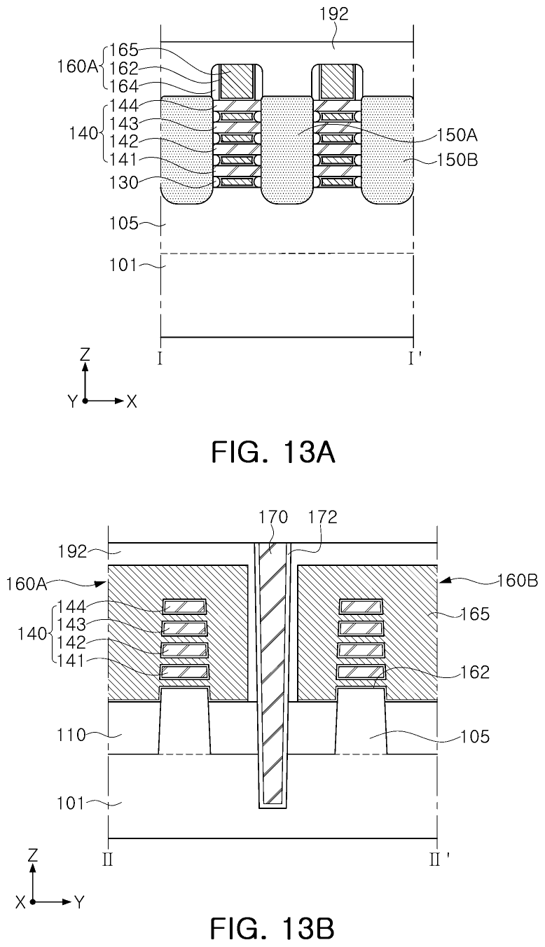

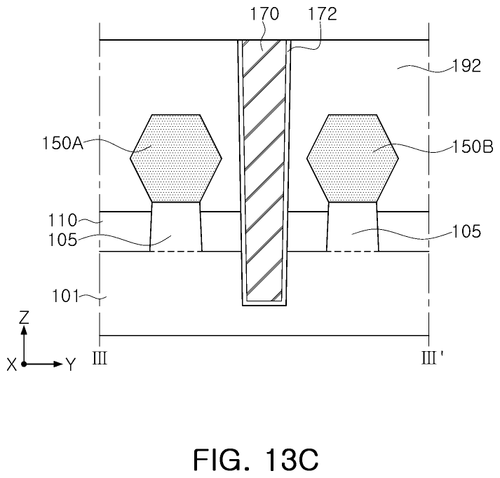

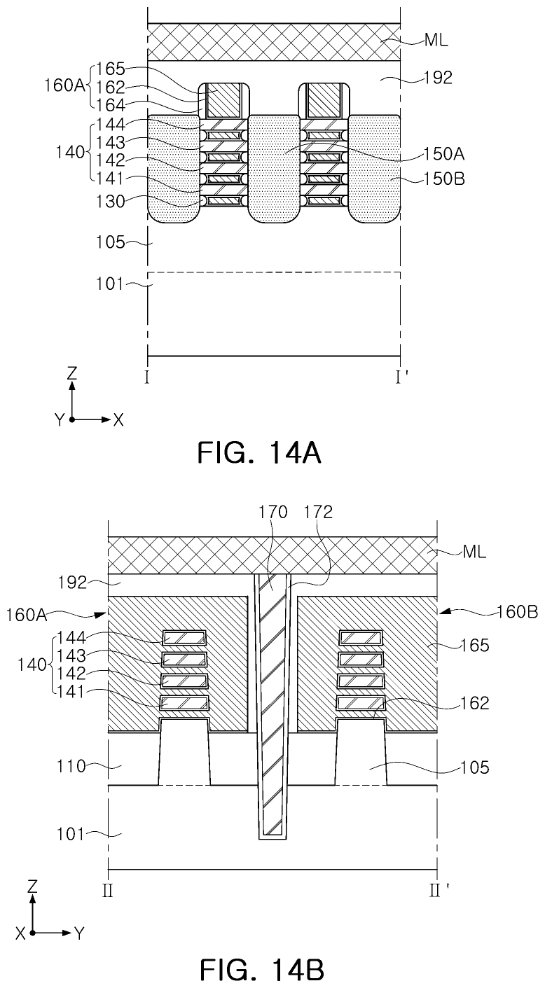

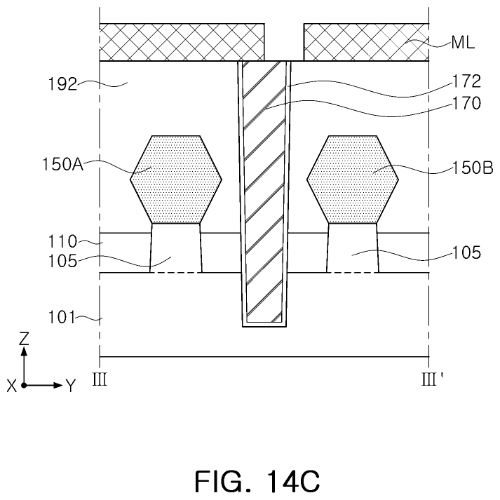

Referring to FIGS. 14A to 14C, a mask layer ML may be formed to expose a region in which the first and second contact plugs 195A and 195B (see FIGS. 1A to 2C) do not extend in a Y-direction.

For example, the mask layer ML may be patterned to expose a region between the first and second contact plugs 195A and 195B adjacent to each other in the Y-direction of FIG. 1A. The mask layer ML may include a plurality of hardmask layers and a photomask layer.

FIGS. 15 to 18 illustrate a cross-section corresponding to FIG. 2C.

Referring to FIGS. 15, the first interlayer insulating layer 192 may be removed to a predetermined depth in the region exposed through the mask layer ML, and an upper insulating layer 192S including a material, different from a material of the existing first interlayer insulating layer 192, may be formed.

A portion of the upper insulating layer 192S may remain through a subsequent process to form the first interlayer insulating layer 192. For example, the first interlayer insulating layer 192 may include a silicon oxide, and the upper insulating layer 192S may include a silicon nitride.

Referring to FIG. 16, openings CR for forming first and second contact plugs 195A and 195B (see FIGS. 1A to 2C) may be formed.

The openings CR may be formed to expose upper surfaces of the first and second source/drain regions 150A and 150B. The vertical insulating layer 172 and the vertical buried structure 170 may also be exposed through a portion of the openings CR. The openings CR may be formed by selectively removing a region of the first interlayer insulating layer 192 other than the upper insulating layer 192S, among regions in which the first and second contact plugs 195A and 195B are to be disposed. However, when the first interlayer insulating layer 192 is removed, a portion of the vertical insulating layer 172 and a portion of the vertical buried structure 170, exposed through the opening CR may also be removed. Accordingly, the vertical buried structure 170 may have an asymmetrical shape in a cross-section in a Y-direction. In some embodiments, a portion of the upper insulating layer 192S may also be removed.

In the example embodiment of FIG. 3A, during the fabricating process, the vertical insulating layer 172 may be rarely removed or relatively less removed and the vertical buried structure 170 may not be removed in the present operation. Accordingly, a trimming process may be additionally performed to additionally remove a left vertical insulating layer 172, and thus, the semiconductor device may be fabricated.

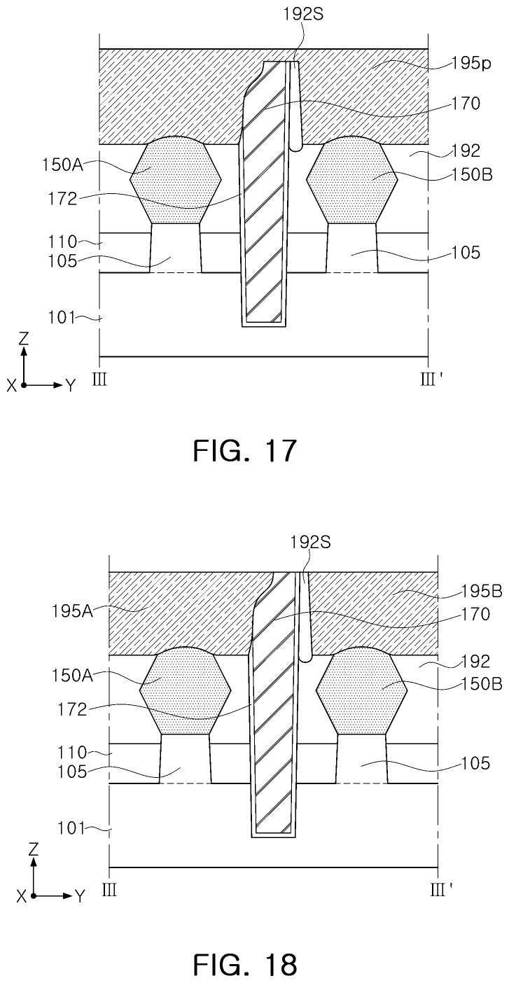

Referring to FIG. 17, a preliminary contact plug layer 195p may be formed to fill the openings CR.

The preliminary contact plug layer 195p may be formed to fill the openings CR and to cover an upper surface of the vertical buried structure 170, an upper surface of the vertical insulating layer 172, and an upper surface of the upper insulating layer 192S disposed between the openings CR adjacent to each other in the Y-direction.

Referring to FIG. 18, a portion of the preliminary contact plug layer 195p may be removed by a planarization process to form first and second contact plugs 195A and 195B.

The planarization process may be performed to expose the upper surface of the vertical buried structure 170, the upper surface of the vertical insulating layer 172, and the upper surface of the upper insulating layer 192S. Accordingly, the first and second contact plugs 195A and 195B adjacent to each other in the Y-direction may be physically separated from each other and may also be electrically separated by the vertical insulating layer 172 and the upper insulating layer 192S. The remaining upper insulating layer 192S may be described as constituting a portion of the first interlayer insulating layer 192, and will not be separately illustrated in drawings below.

In the example embodiment of FIG. 3B, in the fabricating process, the upper insulating layer 192S may be formed to extend left from a portion of the upper surface of the vertical buried structure 170 in the operation described above with reference to FIG. 15. In the present operation, the semiconductor device may be fabricated by relatively reducing a planarization thickness.

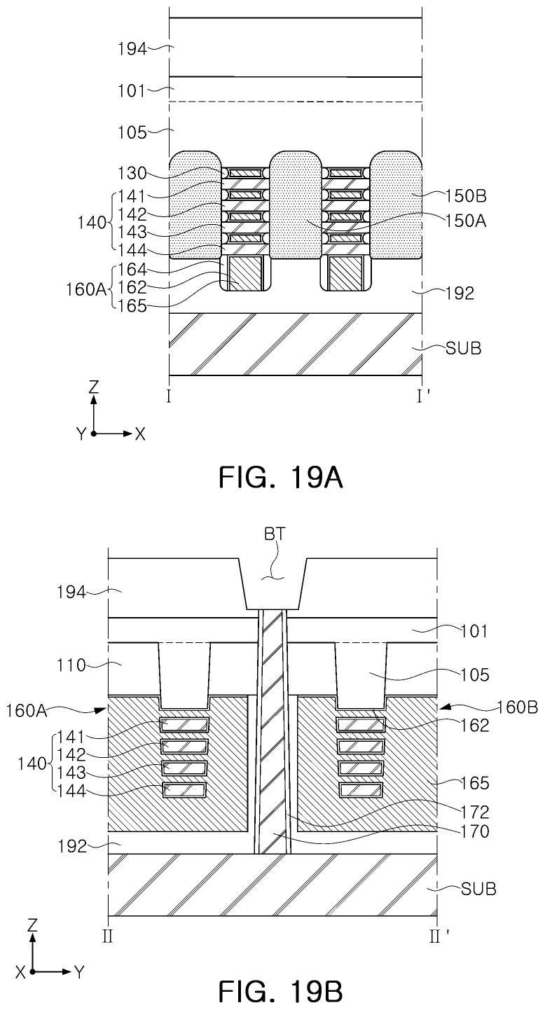

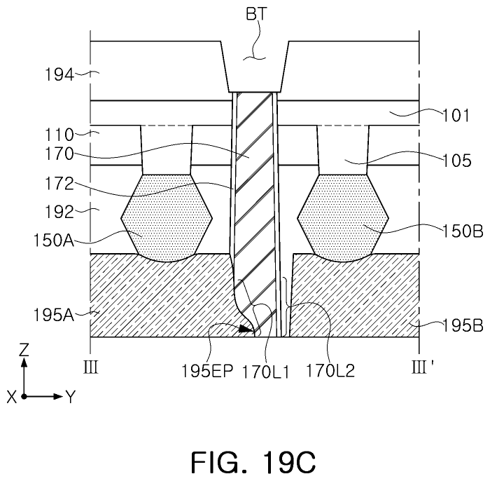

Referring to FIGS. 19A to 19C, the entire structure formed with reference to FIGS. 8A to 18 may be attached to a carrier substrate SUB and a portion of the substrate 101 may be removed, and then a second interlayer insulating layer 194 may be formed and a trench BT may be formed.

The carrier substrate SUB may be attached to the first interlayer insulating layer 192 to perform a process on the lower surface of the substrate 101 of FIG. 18. For better understanding, in FIGS. 19A to 19C, the entire structure is illustrated as being rotated or inverted in the form of a mirror image of the structure illustrated in FIG. 18.

The substrate 101 may be removed from the upper surface of the substrate 101 to a predetermined thickness. The substrate 101 may be removed by, for example, a lapping, grinding, or polishing process. The thickness, at which the substrate 101 is removed, may vary according to example embodiments. In some embodiments, the substrate 101 may be completely removed on the isolation layer 110.

A second interlayer insulating layer 194 may be formed on the thinned substrate 101. A trench BT may be formed in the second interlayer insulating layer 194 in regions in which the horizontal buried structure 180 (see FIGS. 2A to 2C) is to be disposed. When the trench BT is formed, the vertical insulating layer 172 may be removed from the upper surface of the vertical buried structure 170 to expose the vertical buried structure 170.

Referring to FIGS. 2A to 2C together, the trench BT may be filled with a conductive material to form the horizontal buried structure 180, and the carrier substrate 210 may be removed. Thus, the semiconductor device 100 of FIGS. 1 to 2C may be fabricated. The semiconductor device 100 may be packaged in a state in which the horizontal buried structure 180 is disposed thereon, but example embodiments are not limited thereto.

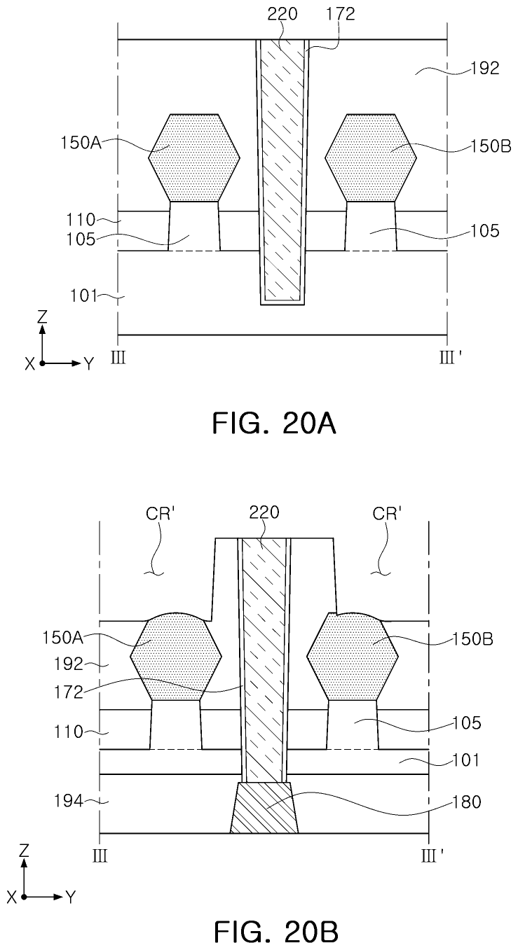

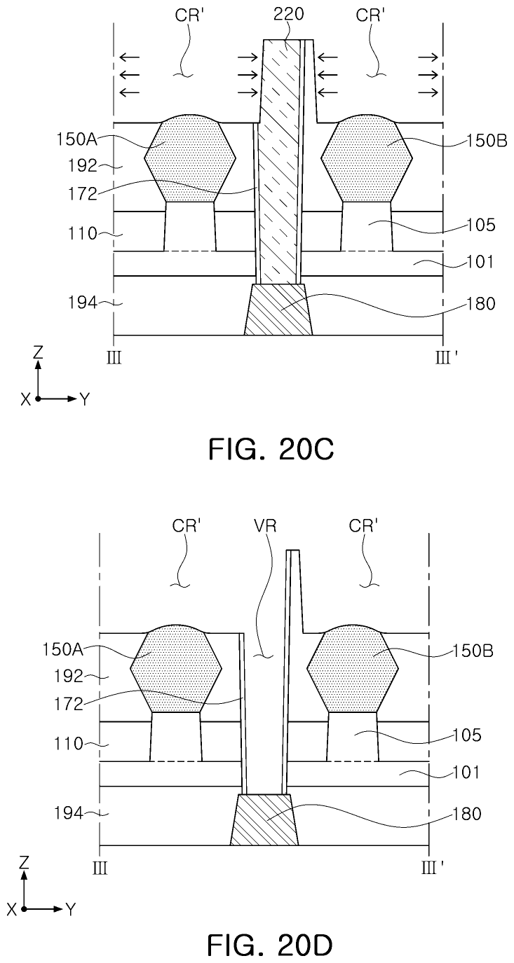

FIGS. 20A to 20D are diagrams illustrating a method of fabricating a semiconductor device according to example embodiments. FIGS. 20A to 20D illustrate an example of a method of fabricating the semiconductor device of FIG. 4, and illustrate cross-sections corresponding to FIG. 4.

Referring to FIG. 20A, the process described above with reference to FIGS. 12A to 12C may be performed in the same manner, and a vertical insulating layer 172 and a vertical sacrificial layer 220 may then be formed.

The vertical sacrificial layer 220 may be formed in a region corresponding to the vertical buried structure 170 (see FIG. 4). A hole may be formed to extend inwardly of the substrate 101 through the first interlayer insulating layer 192, and a vertical insulating layer 172 and a vertical sacrificial layer 220 may then be sequentially formed in the hole. The vertical insulating layer 172 may be formed to conformally cover a bottom surface and internal surfaces of the hole, and the vertical sacrificial layer 220 may be formed to fill the hole. The vertical sacrificial layer 220 may include, for example, a carbon-based material, but example embodiments are not limited thereto. For example, the vertical sacrificial layer 220 may be a spin-on hardmask (SOH).

Referring to FIG. 20B, openings CR′ for forming the first and second contact plugs 195A and 195B (see FIGS. 1A to 2C) may be formed.

Similarly to the description provided with reference to FIG. 16, the openings CR′ may be formed to expose upper surfaces of first and second source/drain regions 150A and 150B. In the present operation, the openings CR′ may be formed to be spaced apart from the vertical sacrificial layer 220 such that the vertical sacrificial layer 220 is not exposed. Accordingly, the openings CR′ may be formed to have a relatively small size, as compared with the openings CR of FIG. 16.

Referring to FIG. 20C, the openings CR′ may laterally expand.

The openings CR′ may expand from side surfaces thereof by a lateral etching process. Accordingly, a portion of the vertical insulating layer 172 adjacent to the openings CR′ may be removed, and a portion of the vertical sacrificial layer 220, exposed after the vertical insulating layer 172 is removed, may also be removed.

Referring to FIG. 20D, the vertical sacrificial layer 220 exposed through the opening CR′ may be removed.

The vertical sacrificial layer 220 may be selectively removed with respect to the vertical insulating layer 172 and the first interlayer insulating layer 192. Accordingly, a vertical opening VR may be formed to extend to be connected the opening CR′.

Referring to FIG. 4 together, the openings CR′ and the vertical opening VR may be filled with a conductive material to form first and second contact plugs 195Ac and 195B and a vertical buried structure 170c. Accordingly, the semiconductor device 100c of FIG. 4 may be fabricated.

As described above, by optimizing a form in which a source/drain contact plug and a vertical buried structure are connected to each other, a semiconductor device having an increased degree of integration and improved electrical characteristics may be provided.

While example embodiments have been shown and described above, it will be apparent to those skilled in the art that modifications and variations could be made without departing from the scope of the present inventive concept as defined by the appended claims.

What is claimed is:

1. A semiconductor device comprising:
first and second active regions on a substrate and extending in a first direction;
a first gate structure and a second gate structure on the first and second active regions, respectively, wherein the first and second gate structures extend in a second direction and are spaced apart from each other in the second direction;
first and second source/drain regions on the first and second active regions, respectively, and adjacent to the first and second gate structures;
first and second contact plugs on the first and second source/drain regions and respectively connected to the first and second source/drain regions; and
a vertical buried structure between the first and second gate structures and between the first and second source/drain regions,
wherein the vertical buried structure comprises first and second side surfaces spaced apart from each other in the second direction, and the first contact plug contacts the first side surface of the vertical buried structure.

2. The semiconductor device of claim 1, wherein an uppermost end of the vertical buried structure is farther than an uppermost end of the first source/drain region from the substrate.

3. The semiconductor device of claim 1, wherein a lowermost end of the vertical buried structure is closer than a lowermost end of the first source/drain region to a bottom of the substrate.

4. The semiconductor device of claim 1, wherein the substrate is equidistant from an uppermost end of the vertical buried structure and an uppermost end of the first contact plug.

5. The semiconductor device of claim 1, wherein an upper portion of the first side surface of the vertical buried structure and an upper portion of the second side surface of the vertical buried structure have different degrees of inclination.

6. The semiconductor device of claim 1, wherein the first contact plug contacts an upper portion of the first side surface of the vertical buried structure, and an uppermost end of the vertical buried structure is closer than an uppermost end of the first contact plug to the substrate.

7. The semiconductor device of claim 1, wherein the first contact plug has a first length in the first direction and has a second length in the second direction, and the second length is longer than the first length, and
the vertical buried structure has a third length in the first direction and has a fourth length in the second direction, and the fourth length is shorter than the third length.

8. The semiconductor device of claim 1, wherein the first contact plug comprises first and second end portions that are spaced apart from each other in the second direction, and
the first end portion of the first contact plug is in the vertical buried structure, in a plan view.

9. The semiconductor device of claim 1, wherein an upper portion of the first contact plug overlaps the vertical buried structure in a third direction that is perpendicular to the first and second directions.

10. The semiconductor device of claim 1, wherein a width of the vertical buried structure in the second direction is in a range of about 10 nanometers (nm) to about 40 nm.

11. The semiconductor device of claim 1, further comprising:
a vertical insulating layer extending on a side surface of the vertical buried structure.

12. The semiconductor device of claim 1, further comprising:
a horizontal buried structure contacting a lower surface of the vertical buried structure.

13. The semiconductor device of claim 1, further comprising:
a plurality of channel layers on the first active region,
wherein the plurality of channel layers are spaced apart from each other in a third direction that is perpendicular to the first and second directions and are in the first gate structure.

14. A semiconductor device comprising:
first and second active regions on a substrate and extending in a first direction;
a first gate structure and a second gate structure on the first and second active regions, respectively, wherein the first and second gate structures extend in a second direction and are spaced apart from each other in the second direction;
first and second source/drain regions on the first and second active regions, respectively, and adjacent to the first and second gate structures;
first and second contact plugs on the first and second source/drain regions and respectively connected to the first and second source/drain regions; and
a vertical buried structure between the first and second source/drain regions,
wherein the vertical buried structure comprises first and second side surfaces that are spaced apart from each other in the second direction, and the first contact plug contacts the first side surface of the vertical buried structure, and
wherein the first contact plug comprises first and second end portions that are spaced apart from each other in the second direction, and the first end portion of the first contact plug is in the vertical buried structure, in a plan view.

15. The semiconductor device of claim 14, wherein at least a portion of the vertical buried structure overlaps the first contact plug in the second direction and a third direction that is perpendicular to the first and second directions.

16. The semiconductor device of claim 14, wherein the vertical buried structure does not overlap the first and second gate structures in the first direction.

17. The semiconductor device of claim 14, wherein the vertical buried structure has a center point in the second direction and has an asymmetric shape with respect to an imaginary line that extending through the center point in a third direction that is perpendicular to the first and second directions.

18. The semiconductor device of claim 14, wherein the vertical buried structure is a first portion of a single layer, and the first contact plug is a second portion of the single layer.

19. A semiconductor device comprising:
first and second active regions on a substrate and extending in a first direction;
a first gate structure and a second gate structure on the first and second active regions, respectively, wherein the first and second gate structures extend in a second direction and are spaced apart from each other in the second direction;
first and second source/drain regions on the first and second active regions, respectively, and adjacent to the first and second gate structures;
first and second contact plugs on the first and second source/drain regions and respectively connected to the first and second source/drain regions;
a vertical buried structure comprising first and second side surfaces that are spaced apart from each other in the second direction, wherein the first contact plug contacts an upper portion of the first side surface; and
a horizontal buried structure contacting a lower surface of the vertical buried structure,
wherein an uppermost end of the vertical buried structure is farther than an uppermost end of the first source/drain region from the substrate.

20. The semiconductor device of claim 19, wherein the vertical buried structure extends between the first and second gate structures in the first direction.
